(19) United States
(12) Patent Application Publication
(10) Pub. No.: US 2003/0227990 A1
(43) Pub. Date: Dec. 11, 2003

(54) Method and apparatus for reducing data dependent phase jitter in a clock recovery circuit

(75) Inventors: Tse-Hsiang Hsu, Hsinchu City (TW); Chih-Cheng Chen, Hsinchu City (TW)

Correspondence Address: BRINKS HOFER GILSON & LIONE, NBC Tower, Suite 3600, 455 N. Cityfront Plaza Drive, Chicago, IL, 60611-5599, US

(73) Assignee: MEDIA TEK INC.

(21) Appl. No.: 10/266,913

(22) Filed: Oct. 8, 2002

(30) Foreign Application Priority Data
Jun. 7, 2002 (TW) 091112413

(51) Int. Cl. H03D 3/24

(52) U.S. Cl. 375/376; 327/156

(57) ABSTRACT

In a method and apparatus for reducing data dependent phase jitter in a clock recovery circuit, a time delay component is connected between the phase detector and the charge controller to cause consecutive ones of ascending and descending pulses from a phase detector to overlap in the time domain. The time delay component cooperates with the phase detector to simultaneously provide the overlapping ascending and descending pulses to a charge controller such that ripples in a control voltage generated by a loop filter and attributed to a current output of the charge controller can be reduced in order to minimize phase jitter of a clock signal from an oscillator circuit.

### CROSS-REFERENCE TO RELATED APPLICATION

This application claims priority of Taiwanese Application No. 091112413, filed on Jun. 7, 2002.

### BACKGROUND OF THE INVENTION

1. Field of the Invention

The invention relates to a clock recovery circuit, more particularly to a method and apparatus for reducing data dependent phase jitter in a clock recovery circuit.

2. Description of the Related Art

Phase locked loops are widely used in devices for frequency control, such as multipliers, demodulators, tracking generators, clock recovery circuits, etc. Currently, synchronized regeneration of data in optical disc mediums, such as CD-ROM, DVD, etc., is achieved with the use of clock recovery circuits. Referring to FIG. 1, a conventional clock recovery circuit 1 is shown to include a phase detector 11, a charge controller 12, a loop filter 13, a voltage-controlled oscillator (VCO) 14, and a frequency divider 15. The phase detector 11 receives an input data signal (DATA) (see FIG. 2A) and a clock signal (CLK) (see FIG. 2B) generated by the frequency divider 15 from a clock output of the oscillator 14. The phase detector 11 generates ascending pulses (UP) (see FIG. 2C) and descending pulses (DN) (see FIG. 2D) according to a phase difference (Δt) between the input data signal (DATA) and the clock signal (CLK). The ascending and descending pulses (UP, DN) are received by the charge controller 12, which generates a current output (I_{cp}) according to the ascending and descending pulses (UP, DN). The current output (I_{cp}) is integrated by the loop filter 13 to result in a control voltage (V_{ct}) (see FIG. 2E), which is used to control the oscillator 14 in order to synchronize the clock signal (CLK) with the input data signal (DATA). When the clock signal (CLK) is synchronized with the input data signal (DATA), the clock signal (CLK) can be used to sample the input data signal (DATA) for data regeneration.

In the conventional clock recovery circuit 1, when the phase of the clock signal (CLK) leads the input data signal (DATA), the phase detector 11 will output a narrower ascending pulse (UP) or a wider descending pulse (DN) to control the charge controller 12 to generate a negative current output (I_{cp}), which is subsequently integrated by the loop filter 13 to result in a smaller control voltage (V_{ct}) for reducing the frequency of the clock output of the oscillator 14. On the other hand, when the phase of the clock signal (CLK) lags the input data signal (DATA), the phase detector 11 will output a wider ascending pulse (UP) or a narrower descending pulse (DN) to control the charge controller 12 to generate a positive current output (I_{cp}), which is subsequently integrated by the loop filter 13 to result in a larger control voltage (V_{ct}) for increasing the frequency of the clock output of the oscillator 14.

It is noted that the phase detector 11 does not output the ascending pulse (UP) and the descending pulse (DN) simultaneously, i.e., the phase detector 11 first generates the ascending pulse (UP) before generating the descending pulse (DN). The control voltage (V_{ct}) is thus generated as a result of the integration of the ascending pulse (UP) and the descending pulse (DN) in their order of occurrence. As such, aside from the desired voltage difference (ΔV) corresponding to the phase difference (Δt), the control voltage (V_{ct}) further contains undesired ripples (Vᵣ). These undesired ripples (Vᵣ) are present even when the phase difference (Δt) is very small. Not only do the ripples (Vᵣ) drive the oscillator 14 to continuously change the phase of the clock signal (CLK), which results in phase jitter of the clock signal (CLK), they also rapidly increase and decrease the frequency of the clock signal (CLK). Therefore, when the clock signal (CLK) is used to sample the input data signal (DATA) in the conventional clock recovery circuit 1, shifting of the sampling points easily occurs to result in data sampling error. Moreover, the phase jitter will lead to the generation of ripples dependent on the frequency of transition edges of the input data signal (DATA), which is otherwise known as data dependent phase jitter.

### SUMMARY OF THE INVENTION

Therefore, the main object of the present invention is to provide a method and apparatus for reducing data dependent phase jitter in a clock recovery circuit.

According to one aspect of the present invention, there is provided a method for reducing data dependent phase jitter in a clock recovery circuit. The clock recovery circuit includes a phase detector for receiving an input data signal and a clock signal, a charge controller connected to the phase detector, a loop filter connected to the charge controller, and an oscillator circuit connected to the loop filter and the phase detector. The oscillator circuit includes a voltage-controlled oscillator, and provides the clock signal to the phase detector. The phase detector generates ascending and descending pulses according to phase difference between the input data signal and the clock signal. The charge controller generates a current output according to the ascending and descending pulses received thereby. The loop filter generates a control voltage for controlling the oscillator circuit to synchronize the clock signal with the input data signal. The method comprises the steps of:

causing consecutive ones of the ascending and descending pulses from the phase detector to overlap in the time domain, and simultaneously providing the overlapping ascending and descending pulses to the charge controller such that ripples in the control voltage generated by the loop filter and attributed to the current output of the charge controller can be reduced in order to minimize phase jitter of the clock signal from the oscillator circuit.

According to another aspect of the present invention, there is provided an apparatus for reducing data dependent phase jitter in a clock recovery circuit. The clock recovery circuit includes a phase detector for receiving an input data signal and a clock signal, a charge controller connected to the phase detector, a loop filter connected to the charge controller, and an oscillator circuit connected to the loop filter and the phase detector. The oscillator circuit includes a voltage-controlled oscillator, and provides the clock signal to the phase detector. The phase detector generates ascending and descending pulses according to phase difference between the input data signal and the clock signal. The charge controller generates a current output according to the ascending and descending pulses received thereby. The loop filter generates a control voltage for controlling the oscillator circuit to synchronize the clock signal with the input data signal. The apparatus comprises:

a time delay component adapted to be connected between the phase detector and the charge controller, the time delay component being adapted to cause consecutive ones of the ascending and descending pulses from the phase detector to overlap in the time domain, the time delay component being adapted to cooperate with the phase detector to simultaneously provide the overlapping ascending and descending pulses to the charge controller such that ripples in the control voltage generated by the loop filter and attributed to the current output of the charge controller can be reduced in order to minimize phase jitter of the clock signal from the oscillator circuit.

According to yet another aspect of the present invention, there is provided a clock recovery circuit that comprises:

a phase detector for receiving an input data signal and a clock signal;

a charge controller connected to the phase detector;

a loop filter connected to the charge controller;

an oscillator circuit connected to the loop filter and the phase detector; and

a time delay component connected between the phase detector and the charge controller.

The oscillator circuit includes a voltage-controlled oscillator, and provides the clock signal to the phase detector. The phase detector generates ascending and descending pulses according to phase difference between the input data signal and the clock signal. The charge controller generates a current output according to the ascending and descending pulses from the phase detector. The loop filter generates a control voltage for controlling the oscillator circuit to synchronize the clock signal with the input data signal.

The time delay component causes consecutive ones of the ascending and descending pulses from the phase detector to overlap in the time domain, and cooperates with the phase detector to simultaneously provide the overlapping ascending and descending pulses to the charge controller such that ripples in the control voltage generated by the loop filter and attributed to the current output of the charge controller can be reduced in order to minimize phase jitter of the clock signal from the oscillator circuit.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic circuit block diagram of a conventional clock recovery circuit;

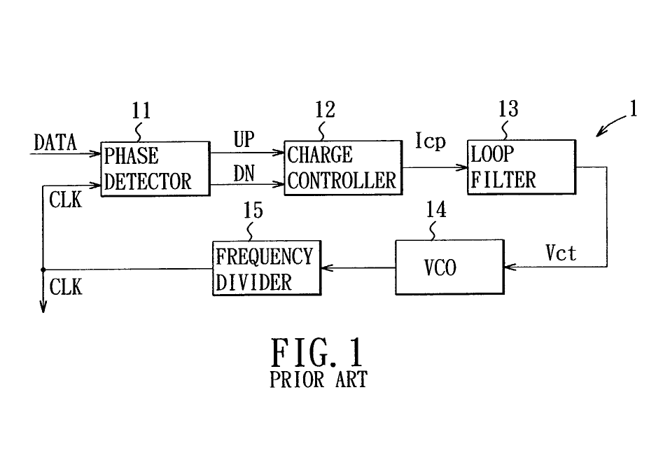

FIGS. 2A to 2E illustrate an input data signal (DATA), a clock signal (CLK), ascending pulses (UP), descending pulses (DN), and a control voltage (V_{ct}) generated in the conventional clock recovery circuit of FIG. 1;

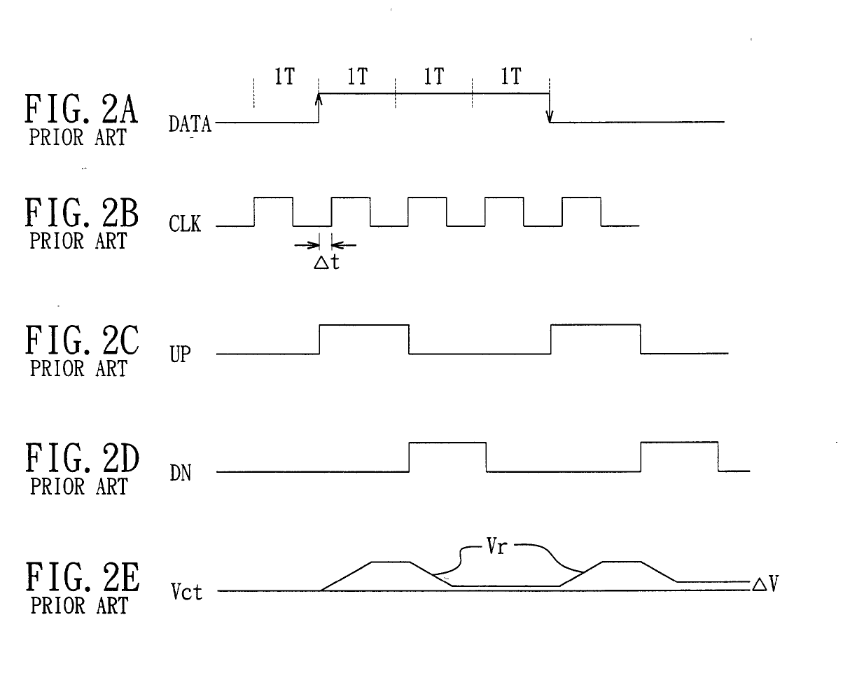

FIG. 3 is a schematic circuit block diagram of a clock recovery circuit that incorporates the preferred embodiment of an apparatus for reducing data dependent phase jitter according to the present invention; and

FIGS. 4A to 4F illustrate an input data signal (DATA), a clock signal (CLK), ascending pulses (UP), delayed ascending pulses (DEL_UP), descending pulses (DN), and a control voltage (V_{ct}) generated in the clock recovery circuit of FIG. 3.

### DETAILED DESCRIPTION OF THE PREFERRED EMBODIMENT

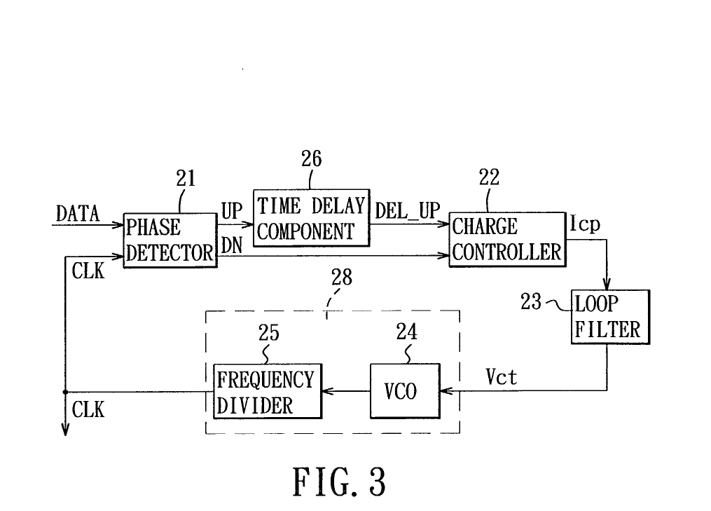

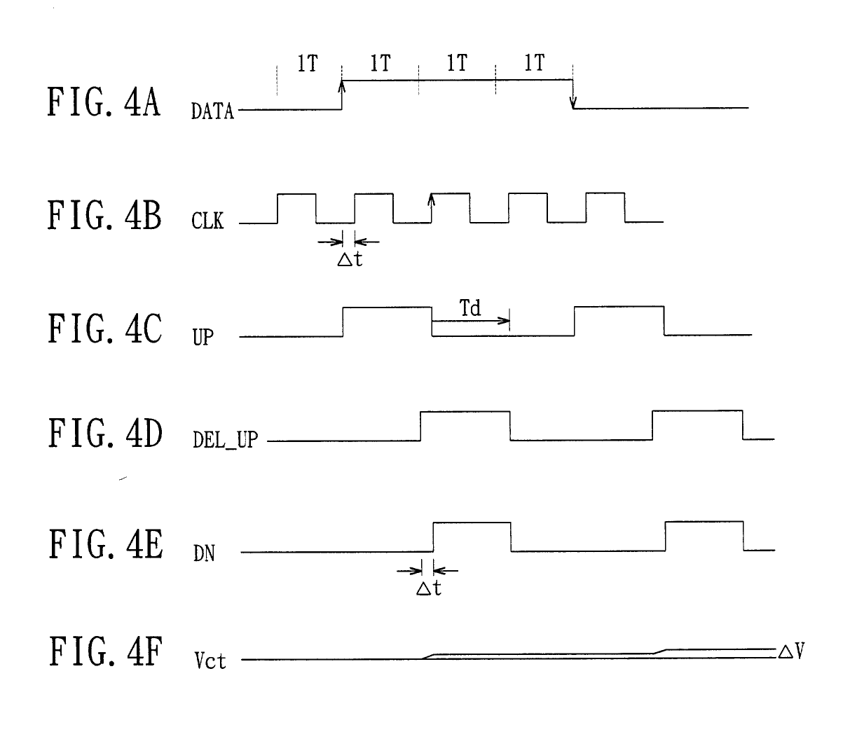

Referring to FIG. 3, the preferred embodiment of a method and apparatus for reducing data dependent phase jitter according to the present invention is shown to be implemented in a clock recovery circuit 2 that is used to generate a clock signal (CLK) for sampling an input data signal (DATA). The clock recovery circuit 2 includes a phase detector 21 for receiving the input data signal (DATA) (see FIG. 4A) and the clock signal (CLK) (see FIG. 4B), a charge controller 22 connected to the phase detector 21, a loop filter 23 connected to the charge controller 22, and an oscillator circuit 28 connected to the loop filter 23 and the phase detector 21. The oscillator circuit 28 includes a voltage-controlled oscillator (VCO) 24 connected to the loop filter 23, and a frequency divider 25 connected to the oscillator 24 and the phase detector 21. The frequency divider 25 processes a clock output from the oscillator 24 to result in the clock signal (CLK) that is provided to the phase detector 21. The phase detector 21 generates ascending pulses (UP) (see FIG. 4C) and descending pulses (DN) (see FIG. 4E) according to a phase difference (Δt) between the input data signal (DATA) and the clock signal (CLK). The charge controller 22 generates a current output (I_{cp}) according to the ascending and descending pulses (DEL_UP, DN) received thereby. Particularly, the ascending pulses (DEL_UP) are associated with an increase in the current output (I_{cp}), whereas the descending pulses (DN) are associated with a decrease in the current output (I_{cp}). The loop filter 23 generates a control voltage (V_{ct}) (see FIG. 4F) for controlling the oscillator circuit 28 to synchronize the clock signal (CLK) with the input data signal (DATA).

Due to the characteristics of the phase detector 21, the starting edge of the ascending pulse (UP) is controlled by the starting or finishing edge of the input data signal (DATA), while the starting edge of the descending pulse (DN) is controlled by the starting edge of a clock pulse of the clock signal (CLK) that follows the ascending pulse (UP). The width of the descending pulse (DN) corresponds to that of the clock pulse of the clock signal (CLK), and there is no overlap between the ascending pulse (UP) and the descending pulse (DN) from the phase detector 21.

In the conventional clock recovery circuit 1 described beforehand, the control voltage (V_{ct}) that is provided by the loop filter 13 to the oscillator 14 contains undesired ripples (Vᵣ) that drive the oscillator 14 to continuously change the phase of the clock signal (CLK), which results in phase jitter of the clock signal (CLK) and which can result in data sampling error.

In order to overcome the aforesaid drawback, the present invention provides an apparatus that includes a time delay component 26, which is connected between the phase detector 21 and the charge controller 22, for introducing a time delay (Td) to one of the ascending and descending pulses (UP, DN) that leads the other one of the ascending and descending pulses (UP, DN) in consecutive ones of the ascending and descending pulses (UP, DN) from the phase detector 21.

In this embodiment, the time delay component 26 introduces the time delay (Td) to the ascending pulses (UP) of the phase detector 21 such that consecutive ones of the ascending and descending pulses (UP, DN) from the phase detector 21 are caused to overlap in the time domain. Preferably, the time delay (Td) is equal to the width of the descending pulse (DN) to maximize the extent of overlap between the consecutive ones of the ascending and descending pulses (UP, DN), and is further equal to one cycle of the clock signal (CLK). Thus, the delayed ascending pulse (DEL_UP) (see FIG. 4D) will have a phase difference with the descending pulse (DN) equal to (Δt), which is the phase difference between the input data signal (DATA) and the clock signal (CLK). In this way, the factor that can cause ripples in the control voltage (V_{ct}) from the loop filter 23 (that is, the non-overlapping ascending and descending pulses from the phase detector 21) can be eliminated. Therefore, when the delayed ascending pulse (DEL_UP) and the descending pulse (DN) are simultaneously provided by the time delay component 26 and the phase detector 21 to the charge controller 22, the increasing current attributed to the delayed ascending pulse (DEL_UP) and the decreasing current attributed to the descending pulse (DN) cancel each other during the period of overlap, such that no current will flow from the charge controller 22 to the loop filter 23 during the overlapping time period. It is only during the non-overlapping time period between the delayed ascending pulse (DEL_UP) and the descending pulse (DN) that the charge controller 22 will generate the current output (I_{cp}) to the loop filter 23, thereby reducing ripples in the control voltage (V_{ct}) generated by the loop filter 23 and attributed to the current output (I_{cp}) of the charge controller 22 in order to minimize phase jitter of the clock signal (CLK) from the oscillator circuit 28. The control voltage (V_{ct}) generated by the loop filter 23 will be formed as a slowly ascending voltage (ΔV), which is used for controlling the oscillator 24 to adjust the clock output thereof according to the phase difference (Δt) between the input data signal (DATA) and the clock signal (CLK).

In summary, according to the method and apparatus of this invention, a time delay (Td) is introduced into the ascending pulses (UP) from the phase detector 21 for overlapping with the descending pulses (DN). Thus, the charge controller 22 will not provide the current output (I_{cp}) to the loop filter 23 during the period of overlap. As such, ripples in the control voltage (V_{ct}) generated by the loop filter 23 and attributed to the non-overlapping ascending and descending pulses are accordingly eliminated. Therefore, the frequency of the clock output of the oscillator 24 will only change in accordance with the detected phase difference (Δt) between the input data signal (DATA) and the clock signal (CLK) to minimize phase jitter of the clock signal (CLK) from the oscillator circuit 28. As such, accurate sampling of the input data signal (DATA) is possible after the clock signal (CLK) and the input data signal (DATA) are synchronized.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. A method for reducing data dependent phase jitter in a clock recovery circuit, the clock recovery circuit including a phase detector for receiving an input data signal and a clock signal, a charge controller connected to the phase detector, a loop filter connected to the charge controller, and an oscillator circuit connected to the loop filter and the phase detector, the oscillator circuit including a voltage-controlled oscillator and providing the clock signal to the phase detector, the phase detector generating ascending and descending pulses according to phase difference between the input data signal and the clock signal, the charge controller generating a current output according to the ascending and descending pulses received thereby, the loop filter generating a control voltage corresponding to the current output of the charge controller for controlling the oscillator circuit to synchronize the clock signal with the input data signal, said method comprising the steps of:
causing consecutive ones of the ascending and descending pulses from the phase detector to overlap in the time domain, and simultaneously providing the overlapping ascending and descending pulses to the charge controller such that ripples in the control voltage generated by the loop filter and attributed to the current output of the charge controller can be reduced in order to minimize phase jitter of the clock signal from the oscillator circuit.

2. The method as claimed in claim 1, wherein the step of causing the consecutive ones of the ascending and descending pulses from the phase detector to overlap includes the step of introducing a time delay to one of the ascending and descending pulses that leads the other one of the ascending and descending pulses.

3. The method as claimed in claim 2, wherein the ascending pulse leads the descending pulse in the consecutive ones of the ascending and descending pulses from the phase detector.

4. The method as claimed in claim 3, wherein the time delay is equal to the width of the descending pulse to maximize extent of overlap between the consecutive ones of the ascending and descending pulses.

5. The method as claimed in claim 4, wherein the time delay is equal to one cycle of the clock signal.

6. An apparatus for reducing data dependent phase jitter in a clock recovery circuit, the clock recovery circuit including a phase detector for receiving an input data signal and a clock signal, a charge controller connected to the phase detector, a loop filter connected to the charge controller, and an oscillator circuit connected to the loop filter and the phase detector, the oscillator circuit including a voltage-controlled oscillator and providing the clock signal to the phase detector, the phase detector generating ascending and descending pulses according to phase difference between the input data signal and the clock signal, the charge controller generating a current output according to the ascending and descending pulses received thereby, the loop filter generating a control voltage corresponding to the current output of the charge controller for controlling the oscillator circuit to synchronize the clock signal with the input data signal, said apparatus comprising:
a time delay component adapted to be connected between the phase detector and the charge controller, said time delay component being adapted to cause consecutive ones of the ascending and descending pulses from the phase detector to overlap in the time domain, said time delay component being adapted to cooperate with the phase detector to simultaneously provide the overlapping ascending and descending pulses to the charge controller such that ripples in the control voltage generated by the loop filter and attributed to the current output of the charge controller can be reduced in order to minimize phase jitter of the clock signal from the oscillator circuit.

7. The apparatus as claimed in claim 6, wherein said time delay component is adapted to introduce a time delay to one of the ascending and descending pulses that leads the other one of the ascending and descending pulses in the consecutive ones of the ascending and descending pulses from the phase detector.

8. The apparatus as claimed in claim 7, wherein the ascending pulse leads the descending pulse in the consecutive ones of the ascending and descending pulses from the phase detector, and the time delay is equal to the width of the descending pulse to maximize extent of overlap between the consecutive ones of the ascending and descending pulses.

9. The apparatus as claimed in claim 8, wherein the time delay is equal to one cycle of the clock signal.

10. A clock recovery circuit comprising:
a phase detector for receiving an input data signal and a clock signal;
a charge controller connected to said phase detector;
a loop filter connected to said charge controller;
an oscillator circuit connected to said loop filter and said phase detector, said oscillator circuit including a voltage-controlled oscillator and providing the clock signal to said phase detector;
said phase detector generating ascending and descending pulses according to phase difference between the input data signal and the clock signal;
said charge controller generating a current output according to the ascending and descending pulses received thereby;
said loop filter generating a control voltage corresponding to the current output of said charge controller for controlling said oscillator circuit to synchronize the clock signal with the input data signal; and
a time delay component connected between said phase detector and said charge controller, said time delay component causing consecutive ones of the ascending and descending pulses from said phase detector to overlap in the time domain, and cooperating with said phase detector to simultaneously provide the overlapping ascending and descending pulses to said charge controller such that ripples in the control voltage generated by said loop filter and attributed to the current output of said charge controller can be reduced in order to minimize phase jitter of the clock signal from said oscillator circuit.

11. The clock recovery circuit as claimed in claim 10, wherein said time delay component introduces a time delay to one of the ascending and descending pulses that leads the other one of the ascending and descending pulses in the consecutive ones of the ascending and descending pulses from said phase detector.

12. The clock recovery circuit as claimed in claim 11, wherein the ascending pulse leads the descending pulse in the consecutive ones of the ascending and descending pulses from said phase detector.

13. The clock recovery circuit as claimed in claim 12, wherein the time delay is equal to the width of the descending pulse to maximize extent of overlap between the consecutive ones of the ascending and descending pulses.

14. The clock recovery circuit as claimed in claim 13, wherein the time delay is equal to one cycle of the clock signal.
